(19) United States
(12) Patent Application Publication
(10) Pub. No.: US 2025/0173647 A1
(43) Pub. Date: May 29, 2025

(54) COMPUTER AIDED GENERATIVE TASK SCHEDULING

(71) Applicant: Autodesk, Inc., San Francisco, CA (US)

(72) Inventor: Philip R. Peterson, Petaluma, CA (US)

(21) Appl. No.: 19/016,604

(22) Filed: Jan. 10, 2025

Related U.S. Application Data
(63) Continuation of application No. PCT/US2024/039031, filed on Jul. 22, 2024.
(60) Provisional application No. 63/516,966, filed on Aug. 1, 2023.

(51) Int. Cl. G06Q 10/0631

(52) U.S. Cl. CPC G06Q 10/063118; G06F 9/455; G06Q 10/063; G06Q 10/06312

(57) ABSTRACT

Methods, systems, and apparatus, including medium-encoded computer program products, for computer aided generative task scheduling, include: obtaining a dataset describing a schedule of one or more projects to be rescheduled, the dataset including tasks to be scheduled, resource requirements, and dependencies between or among the tasks; generating variations of the schedule, each of the variations having different characteristics that determine for the tasks in the schedule when each task is scheduled in time, and each of the variations satisfying the resource requirements and the dependencies; selecting among the different characteristics for the tasks in the variations of the schedule to form a revised schedule of the one or more projects; and providing the revised schedule of the one or more projects for display to a user or for output to manage the one or more projects.

### CROSS-REFERENCE TO RELATED APPLICATIONS

This application is a continuation of, and claims the benefit of priority of, PCT Application No. PCT/US2024/039031, filed on Jul. 22, 2024, and entitled “COMPUTER AIDED GENERATIVE TASK SCHEDULING,” which claims the benefit of priority of U.S. Provisional Application No. 63/516,966, filed on Aug. 1, 2023, and entitled “COMPUTER AIDED GENERATIVE TASK SCHEDULING.” The disclosures of the prior applications are considered part of and are incorporated by reference in the disclosure of this application.

### BACKGROUND

### Technical Field

This specification relates to computer aided task scheduling.

### Description of Related Art

Creating and revising schedules at real-world scale (due to size, complexity, or both) is a time consuming and largely manual process, often prohibiting schedulers from exploring alternative scenarios and causing them to overlook potential opportunities for time, labor, and cost savings. The initial schedule for a project is typically created by hand, requiring a significant amount of time and effort to construct as schedulers endeavor to manually achieve level resource utilization for tasks to be completed while accommodating their project's dependencies and constraints.

Although the first pass at a schedule may be reasonably suitable, inevitably plans will change for any number of reasons. When adjusting their schedule in reaction to change is too time consuming and burdensome, schedulers instead attempt to continue using their original schedule. Consequently, projects make other sacrifices to adhere to their initial plan, frequently in the form of overtime for those working on the project or worse, going over budget on projects or missing important deadlines.

### SUMMARY

This specification describes technologies relating to computer aided generative task scheduling, and in particular, scheduling of tasks such that the utilization of classes of resources are optimized based on the requirements to fulfill the tasks. Generative scheduling provides solution(s) and workflow(s) focused on the problem of scheduling or rescheduling a complex project (or two or more interrelated projects) with efficient and optimized use of resources, and facilitating rapid iteration on alternative scheduling scenarios (either in initial planning or in response to changes that make the original schedule unsuitable) to explore trade-offs given differing time and resource goals and constraints. Generative scheduling is an algorithmic approach that can create time-based task schedules incorporating hierarchical task structure(s), dependencies, time constraints and resource requirements. This approach can be specifically designed to generate schedules that are feasible according to the structure imposed, and more importantly, can be optimized for resource utilization. In addition, the schedules can be generated to (a) increase (or optimize) continuity of tasks with a project and/or sub-project, and/or (b) improve (or optimize) timing for tasks based on assigned priorities, while concurrently optimizing for resource utilization.

In some implementations, generative scheduling leverages machine learning, such as evolutionary algorithm(s), to explore the vast search space of possible feasible schedules. The system can adapt to guide a schedule towards desirable solutions based on one or more synthetic objective measures (also referred to as objective functions) of schedule quality. Note that due to the NP-hard (Nondeterministic Polynomial time) complexity of the problem, exhaustive or even iterative refinement search and optimization methods are generally not applicable to many real-world scheduling problems. Moreover, machine learning approaches that rely on training based on a canonical data set are also generally not usable as there is poor, if any, correlation between one scheduling problem and another.

Particular embodiments of the subject matter described in this specification can be implemented to realize one or more of the following advantages. The functionality of a computer is improved by enabling rapid rescheduling of tasks in one or more projects, even when there are no similar prior project schedules that can be used to guide the rescheduling. The technical field of task scheduling is improved using schedule variation generation (e.g., random variations in task scheduling characteristics) and selection, which solves the technical problem of how to automate task rescheduling when there are no similar prior project schedules that can be used to guide the rescheduling. Moreover, user interface controls are described that provide a continued and guided human-machine interaction to facilitate the technical task of rescheduling a complex project (or two or more interrelated projects), e.g., by employing a resource utilization shaping user interface control.

In some implementations, an evolutionary artificial intelligence (AI) algorithm is used to evolve better schedules from an existing schedule using simplified analogs of basic genetic processes and learned contributors to a good schedule, as measured by objectives, which can be defined using high-level controls that are readily understandable by users. State-of-the-art many-objective evolutionary techniques can be applied to the scheduling problem in a manner that accounts for real-world scale and/or usability. Moreover, the scheduling problem can be addressed without making simplifying assumptions regarding how time is represented or processed.

Generative scheduling, as described in this application, can fundamentally shift creating schedules for complex projects from a laborious manual process to an interactive and productive experience, enabling quicker reactions to dynamic changes and more proactive strategies to mitigate risk as a schedule must be changed in view of new developments. Rather than focus on a single objective problem, such as minimizing “make-span” (the total duration of the schedule) as is typical in the research on the “resource constrained scheduling problem” (RCSP), generative scheduling can focus on the more general, multi-objective problem of optimizing resource utilization with reference to an ideal target utilization over multiple, possibly competing, classes of resources. Moreover, multiple alternative schedules can be rapidly generated, allowing the user of the system to quickly explore alternative approaches to rescheduling a project in response to some change occurring that makes the original schedule unsuitable or even impossible, thereby enabling scheduling changes to be accomplished as fast as changes are required, which can be on a daily or even an hourly basis, as compared to the two or more days or weeks that would be required to reschedule a project using traditional scheduling software. Furthermore, the resulting schedules typically exhibit a higher degree of optimization than is practically possible using traditional scheduling software as existing methods generally or necessarily restrict the set of potential scheduling solutions to an extremely small subset of the overall possibilities.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a system usable to facilitate computer aided generative task scheduling.

FIG. 2 shows an example of a process of generative task scheduling.

FIG. 3 shows another example of a process of generative task scheduling.

FIGS. 4A-4C show an example of a user interface for resource class shaping.

FIG. 5 shows an example of a layered data model, which can be used by the system and/or the processes described in this document.

FIG. 6 is a schematic diagram of a data processing system including a data processing apparatus, which can be programmed as a client or as a server, and implements the processes described in this document.

FIG. 7 shows another example of a process of generative task scheduling.

FIG. 8 shows Table 1, which exhibits an optimized use of each resource class, and Table 2, which provides an alternative schedule.

Like reference numbers and designations in the various drawings indicate like elements.

### DETAILED DESCRIPTION

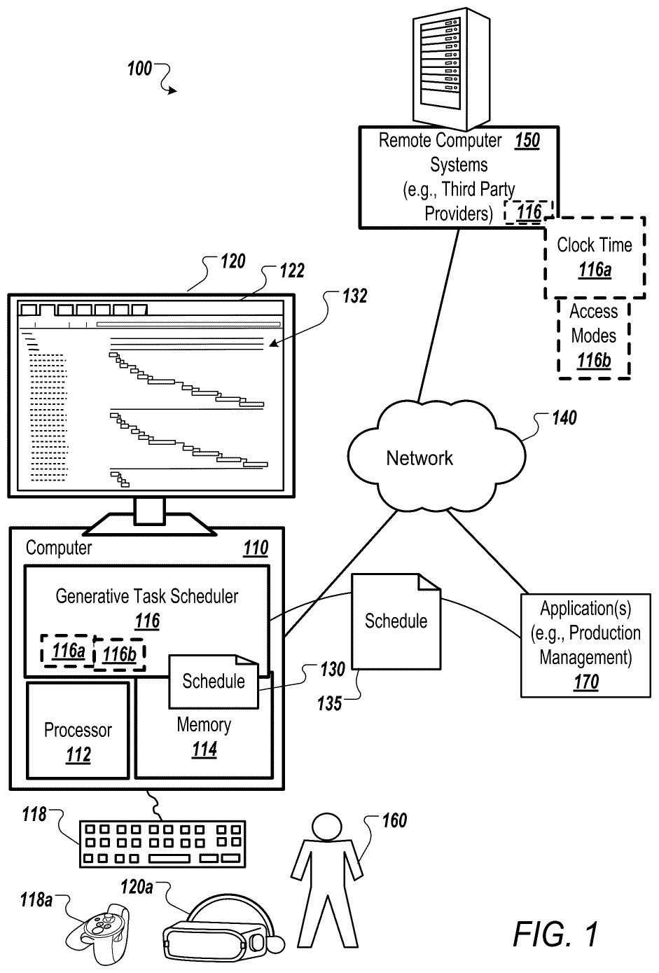

FIG. 1 shows an example of a system 100 usable to facilitate computer aided generative task scheduling. A computer 110 includes a processor 112 and a memory 114, and the computer 110 can be connected to a network 140, which can be a private network, a public network, a virtual private network, etc. The processor 112 can be one or more hardware processors, which can each include multiple processor cores. The memory 114 can include both volatile and non-volatile memory, such as Random Access Memory (RAM) and Flash RAM. The computer 110 can include various types of computer storage media and devices, which can include the memory 114, to store instructions of programs that run on the processor 112, including a generative task scheduler 116, which is one or more programs 116 that implement task scheduling, e.g., such that utilization of classes of resources are optimized based on resource requirements to fulfill the tasks.

The program(s) 116 can run locally on computer 110, remotely on a computer of one or more remote computer systems 150 (e.g., one or more third party providers' one or more server systems accessible by the computer 110 via the network 140) or both locally and remotely. In some implementation, the generative scheduling technology is made available through a cloud-based software-as-a-service accessed from a web browser, which can include one or more code plug-ins. Further, the generative task scheduler 116 can use an open schedule format for a dataset of a schedule, such as scheduling a data store in a JSON (JavaScript Object Notation) schema, where the dataset describes one or more projects to be rescheduled. In some implementations, the generative task scheduler 116 includes one or more user interfaces that enable a user to create the dataset describing an initial schedule. In some implementations, the generative task scheduler 116 imports the dataset describing an initial schedule from another project or scheduling or tracking system and/or program, such as the SHOTGRID® production management product (recently renamed FLOW PRODUCTION TRACKING™) provided by Autodesk, Inc. of San Francisco, California.

In any case, a current schedule 132 (as defined in the dataset) can be presented in a user interface (UI) 122 on a display device 120 of the computer 110, which can be operated using one or more input devices 118 of the computer 110 (e.g., keyboard and mouse). In some implementations, the UI 122 provides a common Gantt view of the data in the current schedule for one or more projects. Regardless of the presentation format of the UI 122, the UI 122 enables a user 160 to view, introspect and adjust resource utilization for one or more projects that are open in the generative task scheduler 116. Thus, the generative task scheduler 116 can be used as a scenario planning program, regardless of whether or not the generative task scheduler 116 can also serve as a primary resource tracking system.

Note that while shown as separate devices in FIG. 1, the display device 120 and/or input devices 118 can also be integrated with each other and/or with the computer 110, such as in a tablet computer (e.g., a touch screen can be an input/output device 118, 120). Moreover, the computer 110 can include or be part of a virtual reality (VR) and/or augmented reality (AR) system. For example, the input/output devices 118, and 120 can include VR/AR input controllers, gloves, or other hand manipulating tools 118a, and/or a VR/AR headset 120a. In some instances, the input/output devices can include hand-tracking devices that are based on sensors that track movement and recreate interaction as if performed with a physical input device. In some implementations, VR and/or AR devices can be standalone devices that may not need to be connected to the computer 110. The VR and/or AR devices can be standalone devices that have processing capabilities and/or an integrated computer such as the computer 110, for example, with input/output hardware components such as controllers, sensors, detectors, etc.

In any case, a user 160 can interact with the generative task scheduler 116 to create multiple scheduling scenarios from a baseline schedule. In each scenario, the user 160 can add, delete, or modify time constraints, specify relative priority, as well as control resource utilization objectives and constraints. For each scenario, the generative task scheduler 116 can be invoked, e.g., using a generative scheduling artificial intelligence (AI) based engine, to generate a feasible and resource optimized schedule automatically. Note that, as used herein, “optimized” (“optimum” or “optimization”) does not mean that the best of all possible schedules is achieved in all cases, but rather, that a best (or near to best) schedule is selected from a finite set of possible schedules that approach an ideal target utilization in light of multiple objectives for the schedule.

One or more selected scenarios can then have their optimized schedule data saved to a scheduling document 130 (locally at computer 110 and/or remotely at computer(s) 150) that can be presented on a display screen, and/or have their optimized schedule data exported 135 for use in production management or other applications 170. The other applications 170 can include physical structure (e.g., office buildings) construction task scheduling, manufacturing (e.g., additive and/or subtractive) machine task scheduling, animation/graphics rendering task scheduling (e.g., a movie production project), and computer resource task scheduling (e.g., predictive utilization, including prefetching of computer resources and balancing competing resources for computation). As will be appreciated, different application domains can have different specific constraints for task scheduling, including potentially location-based constraints. In any case, the core workflow is one of iteration and exploration of multiple alternative schedules (scenarios) by providing simple, direct, and interactive high-level controls to manipulate the schedule characteristics and let the computer aided generative scheduling (e.g., the AI scheduling engine) do the heavy lifting of both optimizing the schedule and ensuring feasibility is preserved.

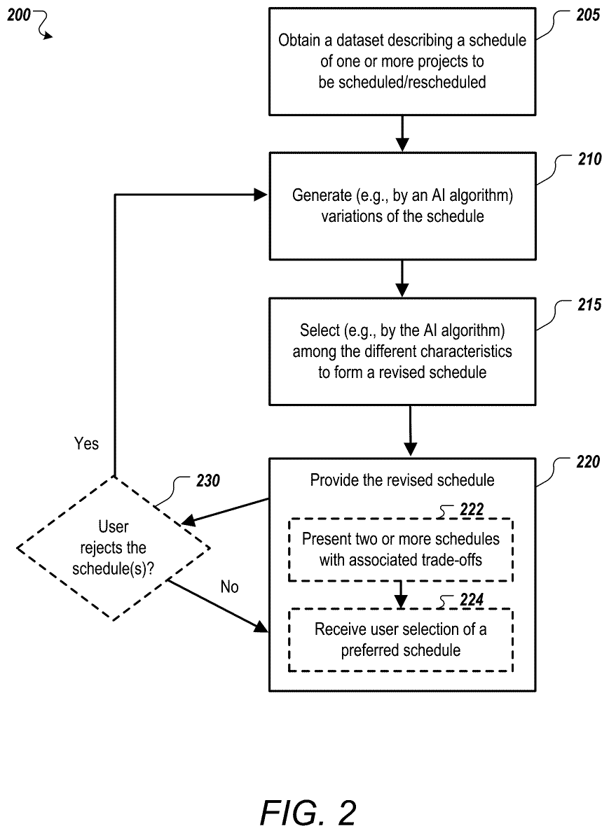

FIG. 2 shows an example of a process 200 of generative task scheduling. The goal of the process 200 is to make optimal use of resources in a schedule for a project. At 205, a dataset describing schedule(s) of one or more projects to be scheduled/rescheduled is obtained by a scheduling computer program (e.g., generative task scheduler 116 and/or scheduling program(s) 604). The obtaining 205 can include generating the dataset to define a schedule or receiving/importing the dataset (defining a previously specified schedule) from a project scheduling or tracking system. In general, project scheduling involves meeting constraints, using resources efficiently and reacting to changes. Scheduling constraints can include dependencies (defined precedence relationship), time constraints (defined relationships to points in time), and bounds (defined intervals in which an activity may start or finish). Resources can have classes (defined types of resources relevant to a project), requirements (defined workloads for various resource classes), and objectives (defined ideal utilizations over time for various resource classes). The dataset that is obtained 205 can include a work breakdown structure of tasks to be scheduled, resource requirements (e.g., workload per resource class), dependencies between or among the tasks, and optionally, one or more scheduling constraints in addition to the dependencies (e.g., at least one time constraint, which may be shared by two or more projects).

The work breakdown structure can be (or be derived from) a description based on standard scheduling terminology, which details the set of activities to be scheduled, arranged in a hierarchy. An activity can be either a task, a milestone, or a summary. A task can represent an activity that requires some set of resources for a specified working duration (resource requirements) where each resource requirement consists of the required class of resource and the number of units of that class needed. A milestone can indicate a key point in the schedule, either indicating the beginning or end of some sub-section of the overall schedule. A summary can consist of a group of activities. Each activity can describe dependencies (precedence relationships) on any other activities as well as specific time constraints, applicable worktime calendars and other parameters. Precedence relationships need not strictly indicate an activity follows its dependency in time. Rather, they can describe a relationship for how it is expected to relate in time. In some implementations, the input dataset is a data model described in an open schedule format schema, e.g., a JSON-based manifest describing the model being defined as part of the generative scheduling product development. In some implementations, a Python library is provided to enable programmatic construction of the open schedule format.

Since the goal of the process 200 is optimal use of resources in a schedule for a project and since the number of possible alternatives for a schedule can be very large (on the order of millions or billions of possible schedules for a typical project, such as a movie production project where multiple projects can run simultaneously, sharing resources, and each of the projects can include tens of thousands of activities and hundreds of thousands of tasks) an exhaustive search of the full scheduling space is not feasible. Thus, the “optimized” schedule that is produced is a schedule that provides a good compromise between the best utilization for each of competing multiple classes of resources, and having the ability to generate new schedules quickly can facilitate the user's ability to explore the tradeoffs among schedules with differing resource availability (timing and/or quantity) or timing constraints to determine “right-sizing”, minimize risk, and manage cost.

At 210, variations of the schedule are generated by the scheduling computer program (e.g., generative task scheduler 116 and/or scheduling program(s) 604). Each of the variations of the schedule can have different characteristics that determine for the tasks in the schedule when each task is scheduled in time, and each of the variations can satisfy the resource requirements, the dependencies, and optionally, one or more scheduling constraints in addition to the dependencies. In some implementations, a set of two or more variations that are generated 210 are random variations, which can include pseudorandom variations. In some implementations, the set of two or more variations are generated 210 deterministically using pre-defined rules and/or heuristics.

The different possible variations that are generated 210 can be based on the concept of float. Any given activity can float within the time bounds that would not cause a violation of any feasible specified constraint. In some implementations, an internal representation of the dataset (e.g., a layered data model, which can include a directed acyclic graph (DAG) as described below) is pre-processed to determine the maximal float bounds for each activity. Based on this, a schedule variant can be generated by combining one of the precedence feasible traversals (e.g., of the DAG) with a value (e.g., in the range [0 . . . 1]) for each activity, defining the relative amount of free float to use, subject to the scheduling of all predecessors according to the traversal order. In some implementations, two or more numeric values are encoded per activity. Moreover, during generation 210, utilization of each resource class can be accumulated.

At 215, a selection is made among the different characteristics for the tasks in the variations of the schedule by the scheduling computer program (e.g., generative task scheduler 116 and/or scheduling program(s) 604) to form a revised schedule of the one or more projects. In some implementations, the generating 210 and selecting 215 are performed by an evolutionary AI algorithm. Further details of such implementations are described below, but other algorithms can be used in various implementations, including other AI algorithms or iterative heuristic algorithms, such as a branch and bound algorithm. In general, any suitable algorithm that handles multi-objective optimization problems (a multi-objective optimization algorithm) can be used. Moreover, the result of the generating 210 and selecting 215 can be a single revised schedule or more than one revised schedule.

In any case, a set of generated schedules can be evaluated according to one or more objective measures (e.g., one or more numeric values can be evaluated per objective) and a subset is selected based on the objective measure(s), attempting to both incorporate the best solutions while maintaining diversity. This subset can then be used to generate a new set, e.g., using genetic algorithm concepts of pseudo-genetic reproduction operators (crossover and mutation). This process can be repeated through subsequent generations until some stopping criteria is met, leaving the evolved solution set. In some implementations, a measure of meaningful improvement over prior generations can be used as a stopping criteria, in combination with a fixed maximum determined according to schedule complexity or acceptable time to produce a result.

The generative process can learn values that contribute to generation of a good schedule, where “goodness” is classified according to the objective(s). The final solution set can be the output result, exhibiting a set of solutions that are optimized according to the measures. In some cases, the output result is a single solution for the schedule, but in other cases, multiple solutions can be presented, exhibiting different trade-offs as a result of the multi-objective problem for scheduling. In some implementations, each of the final solutions has associated with it a simple metric indicating (per objective measure, e.g., per resource class) its similarity to the desired optimal utilization goal.

Note that the core criteria used for evaluating the quality of a schedule can include a multi-objective (often, many-objective) formulation. Specifically, the goal is to optimize the resource utilization of each class of resources required by the schedule. For each resource class, this resource utilization can be computed as a time-series during schedule generation. This forms a set of data that has a strong similarity to a (discrete) probability distribution function. A single objective measure can be formed by creating a target, ideal distribution function (including potentially by user controls to shape that distribution, as described further below), and the actual distribution can then be compared to the ideal distribution for similarity, thus producing the objective measure/function. Note that additional objective measures relevant to sequential continuity, relative priority and other factors can be introduced as additional dimensions in the multi-objective formulation. For example, an objective measure of sequential continuity can seek to minimize the amount of delay introduced between the start of a task and the finish of a dependent task. An objective measure of relative priority can quantify the scheduled times of two or more tasks of different priorities correlated with their desired relative priority regardless of dependencies.

At 220, the revised schedule(s) of the one or more projects are provided by the scheduling computer program (e.g., generative task scheduler 116 and/or scheduling program(s) 604). This can involve presenting the revised schedule(s) for display to a user (e.g., on in UI 122 on display device 120 for user 160 to review) and/or for output to manage the one or more projects (e.g., to a scheduling document 130 and/or via a schedule data export 135 for use in production management or other applications 170).

In some implementations, two or more revised schedules are presented 222, optionally with associated trade-offs shown for the different schedules, e.g., the simple metric referenced above, and a user selection of a preferred schedule is received 224 before a specific revised schedule is output to manage the one or more projects. In some implementations, the user is presented with an option to reject 230 all the provided schedule(s), and the process 200 then returns to generation 210 of new variations, e.g., with newly selected parameters therefor.

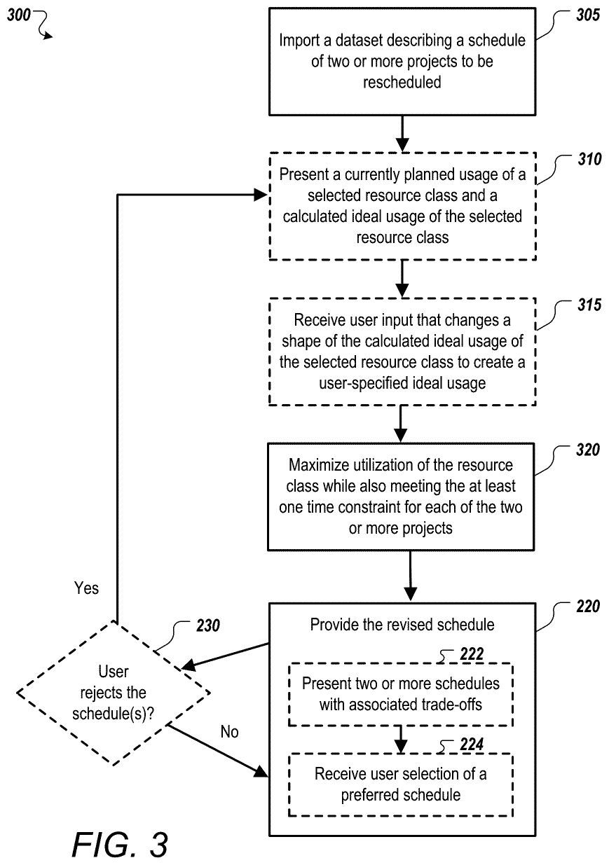

FIG. 3 shows another example of a process 300 of generative task scheduling. At 305, a dataset describing schedule(s) of two or more projects to be rescheduled is imported by the scheduling computer program (e.g., generative task scheduler 116 and/or scheduling program(s) 604). In this example, the two or more projects share at least one resource class, but in general, two or more projects can each have partially or wholly independent resource requirements. Moreover, the dataset that is imported 305 can include a work breakdown structure of tasks to be scheduled, resource requirements (e.g., workload per resource class), dependencies between or among the tasks, and at least one time constraint for each of the two or more projects.

In some implementations, a currently planned usage of a selected resource class (e.g., a user selected resource and/or the at least one resource class shared by the two or more projects) and a calculated ideal usage of the selected resource class are presented 310 by the scheduling computer program (e.g., generative task scheduler 116 and/or scheduling program(s) 604). Then, user input is received 315 by the scheduling computer program (e.g., generative task scheduler 116 and/or scheduling program(s) 604) that changes a shape of the calculated ideal usage of the selected resource class to create a user-specified ideal usage of the selected resource class. A revised schedule can then be formed by modifying the currently planned usage of the selected resource class to approximate the user-specified ideal usage based on an objective function for work distribution expressed as a deviation of the selected resource class's utilization from the user-specified ideal usage of the selected resource class. For example, at 320, utilization of the at least one resource class is maximized (e.g., by an AI algorithm performing the generating 210 and the selecting 215 in generative task scheduler 116 and/or scheduling program(s) 604) while also meeting the at least one time constraint for each of the two or more projects.

In some implementations, the revised schedule(s) of the one or more projects are the provided 220, as described above. In some implementations, at least one of the revised schedule(s) automatically becomes the new schedule and the process 300 returns to 310. Because the revised schedule can be generated very rapidly, the user can be provided revised schedules in real time, and the process 300 can function as an effective scenario planning program.

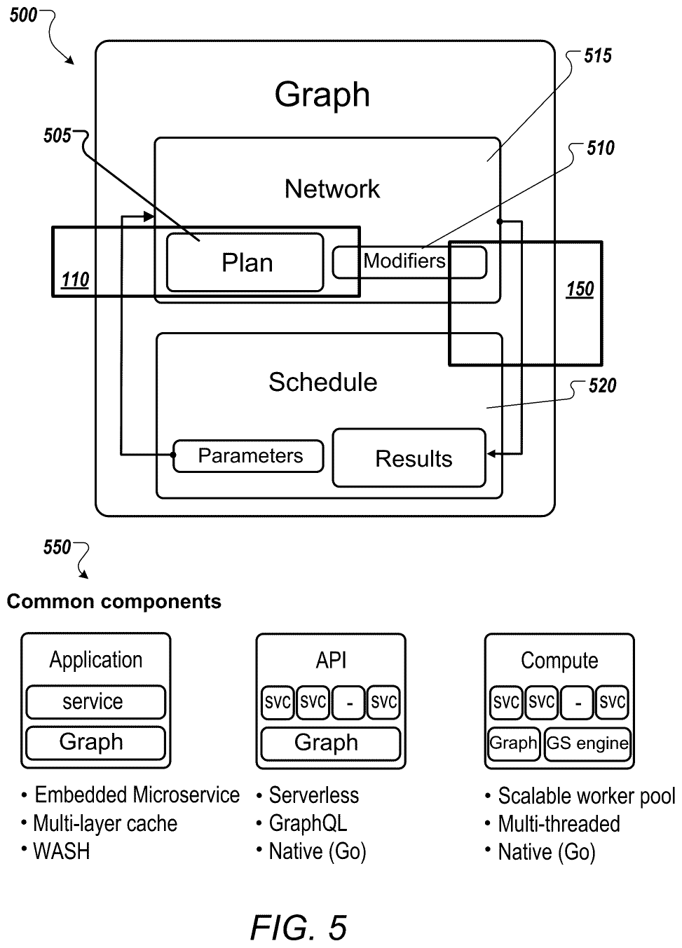

In some implementations, an evolutionary AI algorithm (also referred to as a genetic algorithm) is used for the maximizing 320 of utilization of one or more resource classes. The genetic algorithm reproduction operators (crossover and mutation) require a representation of mutable schedule parameters that is amenable to these operators, and in such a way as to encourage favorable traits while maintaining diversity (avoiding premature convergence or over-breeding). Two sets of parameters that can be used to affect schedule generation are (1) the graph (e.g., the DAG discussed in connection with FIG. 5) traversal order and (2) the relative float per activity. The float can be parameterized as a vector of length n, where n is the number of nodes in the graph, and each value is in the range [0 . . . 1] representing the amount of relative float.

The traversal order can also be encoded in the same manner with a second vector where each [0 . . . 1] value represents the priority of a node in the traversal order subject to precedence satisfaction. Encoding in this manner can guarantee that all possible variations can exist, and that operators well-suited to the problem domain can be used. Moreover, these operators can be made to guarantee that the offspring produced will all constitute feasible schedules. In some implementations, Simulated Binary Crossover and Polynomial Mutation are used for their favorable properties in this respect.

Further, in some implementations, the specific sorting and selection criteria used during the evolutionary process is based on the Adaptive Geometry Estimation technique (AGE-MOEA), which estimates the Pareto optimal front for multi-objective problems using non-Euclidean geometry. This algorithm, for each generation, sorts the set of schedules using a non-dominated sorting method based on the multi-value objective measure (per resource class) and then estimates the Pareto optimal front and selects candidates to form the parents of the next generation based on a complex survival score to target sampling that front uniformly with diversity coverage.

Finally, additional optimizations and meta-heuristics can be interleaved in both the schedule generation and evolutionary processes in various implementations. These can include local iterative search to attempt to satisfy strict limits on maximal utilization, local improvements on results based on bi-directional justification and refinement, and preconditioning distribution functions to seed initial sets of schedules based on heuristics that promote continuity within work breakdown structure hierarchy.

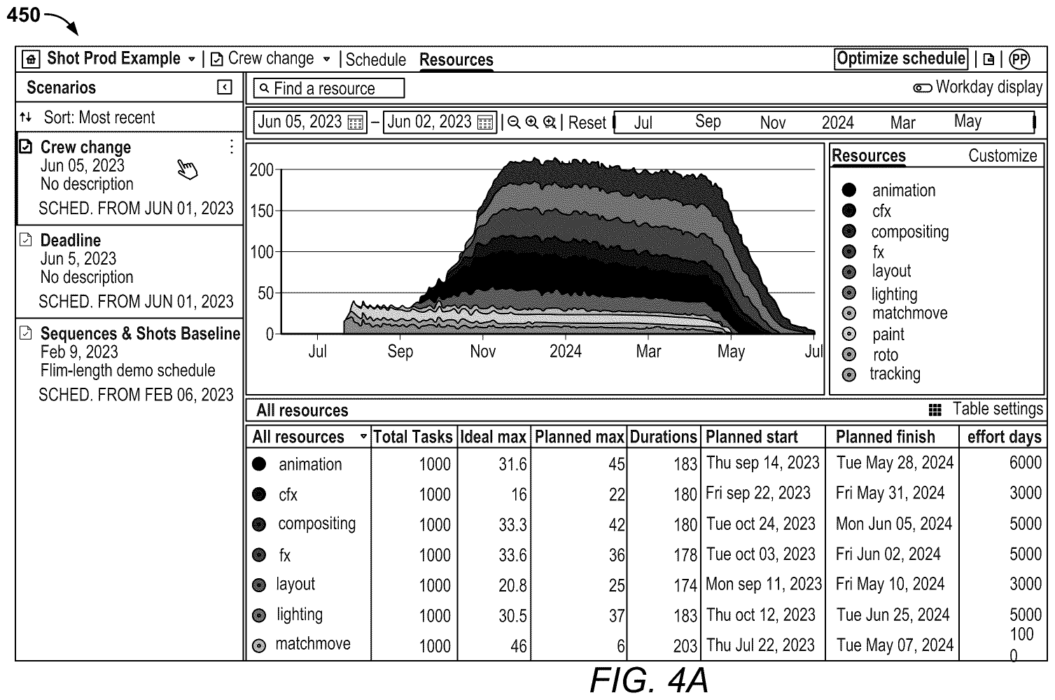

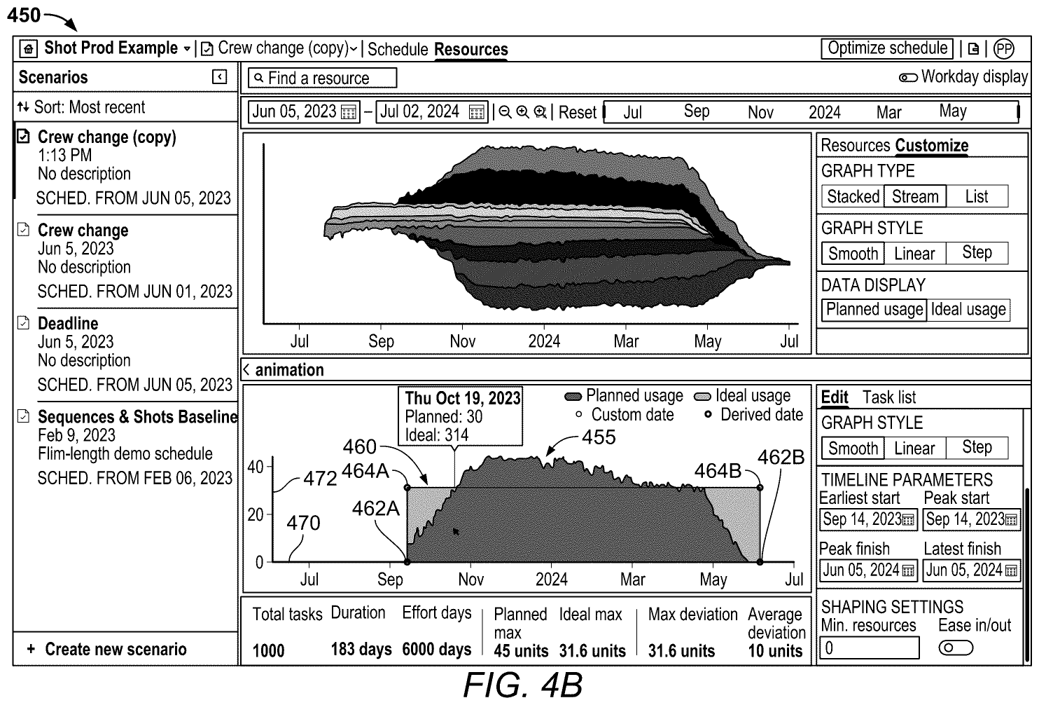

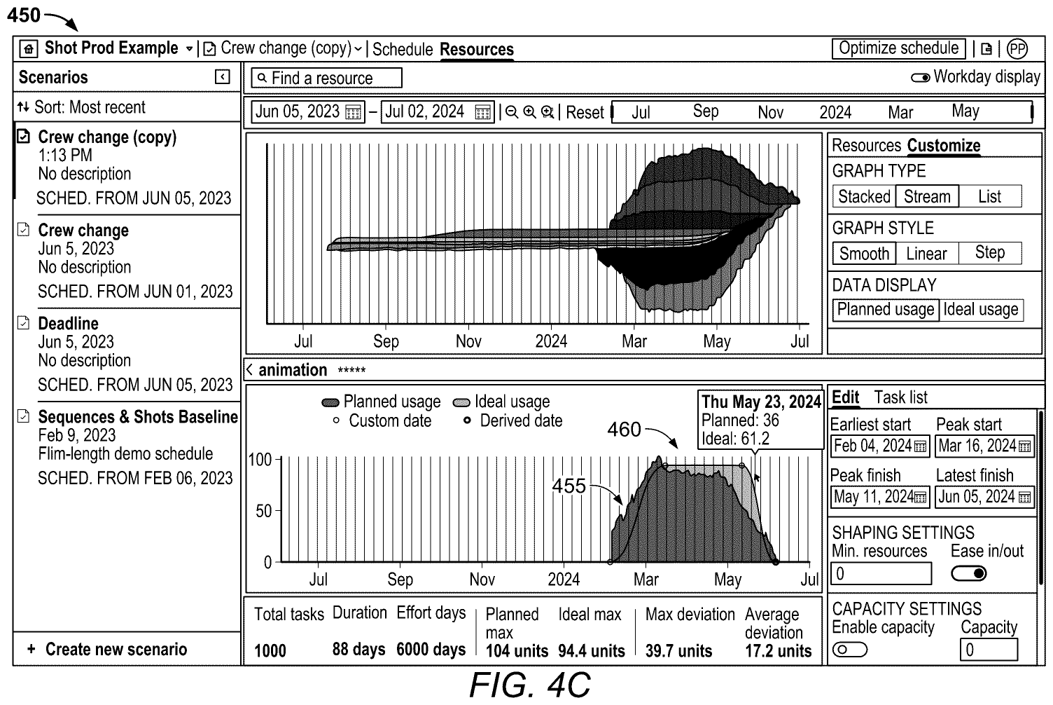

FIG. 4A shows an example of a user interface (UI) 450 presenting multiple resource classes associated with one or more projects to be rescheduled. FIG. 4B shows the UI 450 after a resource class 455 has been selected, where the UI 450 shows the actual utilization of the resource class 455 in the current schedule by showing time on a first axis 470 and workload on a second axis 472. In addition, the UI 450 shows a UI element 460 (a box in FIG. 4B) representing the theoretical ideal resource utilization, which can be computed automatically based on the earliest possible start date and the latest possible end date for the one or more activities (each including multiple tasks) in one or more projects that utilize this resource class, i.e., based on the scheduling constraints. Resource shaping can then be used to allow the user to modify the theoretical ideal resource utilization interactively thru the UI 450.

To facilitate this process, the UI element 460 can include one or more parts that the user can modify directly to change a start date for usage of the selected resource class and/or an end date for usage of the selected resource class. For example, the user can select and drag a start date UI element 462A and/or an end date UI element 462B to adjust the start and end dates for usage of the selected resource class. As another example, the user can select and drag a ramp-up curve UI element 464A and/or a ramp-down curve UI element 464B to modify the ramp-up and ramp-down curves for the workload for the selected resource class. In some implementations, Bezier curves are used to define the ramp-up and ramp-down curves, but various types of UI elements can be used.

FIG. 4C shows the UI 450 after the start date has been moved forward and the ramp-up and ramp-down curves have been adjusted. As will be appreciated, this is but one example of the types of modifications the user can make. In some implementations, changing the start or end dates using the UI element 460 causes the system to automatically recompute the total area under the UI element 460 (the resource utilization target) according to all the work schedule calendars (which can be discontinuous work days) and the scheduling constraints. Also, in some implementations, changing the ramp-up or ramp-down using the UI element 460 causes the system (e.g., the AI algorithm) to automatically optimize the schedule to achieve the specified target workload ramp-up and/or ramp-down.

Thus, resource shaping via UI element 460 is doing two things: (1) it provides high level controls to create actual realistic objective functions for the resource utilization to be used by the scheduling computer program when optimizing the schedule, and (2) it facilitates ease of use in that the user can be provided a graphical user interface (GUI) to provide a general description of what the resource utilization should look like, and then let the scheduling computer program figure out both how to derive the correct objective function and update the resource utilization target in real time, and then use that to determine a revised schedule for this new resource utilization target. Note that this adjustment via the UI 450 is not just changing the objective function that the scheduling computer program can use to do the optimization; it is also using it as a form of control on the schedule.

The ideal distribution definition can be combined with time constraints as a methodology for high-level control and manipulation. Also, rather than representing and/or deriving the model distribution function as simply a fixed amount, the model distribution function can be represented and/or derived with user-defined monotonic curves. Also note that the amount of time available to work on a given day is variable from day to day, depending on work schedules. So when computing the area, it is not a simple sum/integral, but rather is computed in discontinuous time. Computing the distribution function with a non-uniform and discontinuous independent variable is important for real-world problems with varying work schedules including variable working time per day.

Referring again to FIG. 1, in some implementations, the objective function for work distribution uses a non-uniform and discontinuous independent variable that represents clock time 116a as a monotonically increasing, cumulative amount of available working time since a start time. The computer resources required to perform schedule graph evaluation is dominated by indexing forward and backward in time according to some clock. However, in real-world scheduling, the clock can be both discontinuous and non-uniform (although monotonic). Furthermore, there can be many different clocks within the same schedule and key operations for the scheduling computer program can require transforming from one clock space to another. The use of the non-uniform and discontinuous independent variable that represents clock time 116a facilitates both indexing forward and backward in time (since this can be done in the shared clock time 116a) and also transforming from one clock space to another (since each different clock space is readily convertible to and from the shared clock time 116a).

In some implementations, the system provides access modes 116b including both a concurrency-safe lazy-construction mode and a high-performance lock-free read-only mode for assessing the clock time 116a. For both of these modes, indexing and delta computation can be accomplished against a monotonic, cumulative representation of available working time that allows for efficient binary search methods to increment over the discontinuous and non-uniform time. Moreover, time can be aligned with a normalized start-of-day to factor out time-zone information from computation. A day's clock can be represented as the number of working seconds (relative time) vs. absolute time. This is efficient for the specific case of scheduling (although not for general time/clock representation) and thus reduces the computational resources required to perform generative scheduling as described in this document.

In some implementations, to define an objective function per resource class (which can be further restricted to be per-project), the total workload to be scheduled is considered. An ideal objective function can be described as a discrete distribution of workload over a time range. The integral of the ideal objective function should equal the total workload. From a given schedule variation, the actual discrete distribution of work can be computed. A measure of divergence of the actual from the ideal serves as the value of the objective function.

An ideal distribution can be derived by scaling a unit distribution such that the discrete integral (or simply the area under the distribution curve) equals the total workload. A common distribution can be defined with a start and finish point in time and optionally points at which the distribution is “ramped” up to its peak value and “ramped” down from its peak value. The interpolation between the start/finish and ramp points can employ a Bezier curve, as discussed above, or the interpolation can be linear or some other appropriate non-linear definition. Note that the computation of the scaling factor of the unit distribution should factor in that it be both non-uniform (in terms of available workload that can be assumed) or discontinuous in the time dimension. Furthermore, in addition to defining an objective distribution, the start and end points of the ideal curve also serve as constraints such that it forms the bounds for which tasks requiring that class of resource have an earliest allowable start time and latest allowable finish time.

Referring again to FIG. 4B, the adjustment of the control points 462A, 464A, 462B, 464B of the ideal curve 460 can cause computation in real time of the scale of the workload distribution such that its integral matches the total workload according to the computation requirements defined above. Additionally, it is possible to reference a time series of available capacity for a resource class. The ideal curve 460 can then clipped (if necessary) to ensure it does not exceed the available variable capacity and the scale of the resulting ideal curve compensating for any capacity clipping. In some implementations, the scheduling computer program continuously calculates the number of resources needed based on work to be done and work schedules (including non-working days and scheduled overtime) in response to user edits of the ideal curve 460 for the resource class.

A schedule definition can include one or more work schedules (or working time calendars), where each work schedule defines the amount of working time available on a given date. Each task has an associated work schedule. In generating a schedule, each task will have an earliest possible start time based on the scheduled timing of its predecessors (according to dependencies) and optionally constraints. In order to compute the actual scheduled start time, the earliest start time should be transformed into the working time calendar of the task to be scheduled. And, in order to compute the finish time of the task, the duration in working time should be added to start time in the working time calendar of the task. This involves computing time deltas/offsets (essentially addition) in a non-uniform and discontinuous space. Doing this efficiently (as described in this document) enables achievement of the desired (e.g., real time) performance since the affected operations are performed a large number of times during a rescheduling of a real-world project. Additionally, it is useful to support the concept of being date/time independent of time zone. Without this efficient approach, an iterative forward search and increment would be needed, which if durations are not very short, requires many steps forward with effort increasing relative to the length of duration(s).

To achieve the desired efficiency, a work schedule for a range of interest can be transformed into a cumulative amount of working time from a given starting point in time. Specifically, define a start day as the number of seconds from an epoch in a universal time clock (UTC). For each subsequent day, in the entry for the clock (referred to as a “timetable”), the cumulative amount of working time (inclusive of the end of that day) is stored. This defines a clock that is time-zone free (i.e., relative time), that is possibly non-uniform and discontinuous. The efficiency comes from exploiting this distribution of the clock. So, given any time point, the actual date time can be derived using a binary search to find the interval in which the time point exists, and then convert from cumulative to relative time, which can in turn be simply transformed to an actual date/time. For example, even with a total schedule duration of approximately three years, a maximum of ten increments are required for durations of any amount up to three years. Using a purely forward search strategy, any durations of ten days or greater (and possibly less) will exceed this and scale inefficiently. Additionally, these timetables can be built greedily (including in a multi-threaded context) and then be continually queried using a read-only, lock-free implementation 116b for even further improved performance.

To do a rescheduling of a project, the calendars associated with multiple resources are evaluated many times, and each of these calendars can have different work days and available hours per work day. The custom clock implementation allows each different work calendar to be represented in universal time, where the clock represents how much available work time has elapsed since the beginning of time for the project. Thus, a single clock time for a resource can correspond to many different real clock times, and clock time for that resource only advances during working hours for that resource. This implementation for the clock enables efficient searches (e.g., using a binary search algorithm) for actual time points during rescheduling and thus provides high performance at scale. Note that unique clocks can be implemented not just at the level of individual resources, but also at the level of individual tasks. Each task can have its own unique clock time since a task may require more than one resource, and such a task will have a composed calendar that covers all the resources required for that task.

Furthermore, FIG. 5 shows an example of a layered data model 500, which can be employed by the system and/or the processes described in this document in order to reduce the computational resources used and/or reduce the bandwidth consumed by computer communications between the program 116 on the local computer 110 and the program 116 on the remote computer 150, thus enabling the computer to actually perform a scheduling process in a reasonable amount of time on complex, real-world project(s) by reducing the operational latency between a user performing an action on the UI and display of the result of performing said action. The layered data model 500 can be understood as three layers (although the three layers need not have hard boundaries between each layer) where each layer differs in terms of what that layer models and how that layer is persisted (saved for long term storage) and transported (communicated over a network).

While different numbers of layers can be used in various implementations, the design of the layered data model 500 can address the following issues. A fundamental characteristic of scheduling graph models is that local changes can have propagating effects to some (or all) of the nodes in the graph. This is not typically a problem in desktop applications where the data set is resident. However, in cloud-based services, persistence exists server-side with delivery of data to a client over some network protocol. This presents a problem as data set size scales up as a single local change can require (a) re-load and re-persistence of the entire data model; and/or (b) re-transmission of the entire data model. This problem is typified by REST APIs (Representational State Transfer Application Programming Interfaces) in a service or micro-service architecture. These problems are also exacerbated when using a multi-tenant and/or server-less architecture where cache coherence is difficult. Rather than use REST mechanism to propagate local edits, which can result in overload of the network connection and significant increases in operational latency due to a high level of sending and receiving data from the cloud, the layered data model 500 can be used to achieve composability (i.e., subcomponents of a program implementation, e.g., modular software routines, are readily combinable to form complex systems).

In some implementations, the first layer 505 of a three layer data model specifies a topology of a graph representing the schedule. This first layer represents the largely immutable data topology of the graph and can also represent a point-in-time view of mutable attributes. Essentially, a schedule topology is established that is relatively fixed across a number of schedules (encoding work breakdown structure and schedule topology are the basic plan, as shown). For example, the generated or imported dataset (e.g., a JSON-based manifest) can be transformed (for internal system representation) into a single partition, directed acyclic graph (DAG). This DAG is based on the precedence relationships from the input model, but can also includes a transformation of all hierarchical constructs and constraints into a single unified DAG model for efficient evaluation. The internal representation can be optimized specifically for schedule generation and can include an implementation of de-duplicated discontinuous monotonic clocks (clock time 116a) for computing time offsets with multiple worktime calendars.

The second layer 510 of the three layer data model specifies at least edit operations that make local changes to the first layer. Sparse edit operations can be used as modifiers, as shown, to the underlying schedule topology. These edit operations can be embedded and composed into an evaluation graph 515 (Network) that can work at runtime. Moreover, schedule variation encoding can go into a separate datastream that is composed and layered on top of the evaluation graph 515, which facilitates performant caching, data transport, and performing edit operations that can result in propagating large amounts of change in the overall resulting composed evaluation data structure but can be described by small localized changes in the layered data model, in a guaranteed reproduceable manner.

The third layer 520 of the three layer data model specifies the graph representing the schedule, including all details of the dependencies between or among the tasks in the schedule and all scheduled start and end times for the tasks in the schedule. In addition, the third layer 520 can include in the specification of the graph representing the schedule the characteristics that define the schedule variant as well as other parameters determining the potential range of variability for each task. The third layer can be understood as a flattened layer of highly mutable properties of the entire graph which contains the propagation effects.

Further, in some implementations, the scheduling computer program runs at least on a server computer 150 remote from a client computer 110 operated by the user, the first layer 505 of the layered data model 500 is fully loaded into memory of the client computer 110, and updates to the second layer 510 in response to edit operations are concurrently performed locally at the client computer 110 and persisted to the server computer 150. In some implementations, in addition to storage and operations server-side, the client 110 maintains a 3-layer cache for the current and recent working sets in memory, which can be implemented as an embedded service running on a different thread. The cache can be used to hydrate (populate or fill) a complete evaluation data structure by loading the first layer 505 from the cache, applying the second layer 510, and then evaluating to generate the third layer 520.

The combination yields an efficient, complete live data model. On an edit operation, the only data that needs to transit to the network is the local changed attributes (an element of the second layer). The result of the operation can be evaluated optimistically and deterministically from client-cache concurrent to the server-side persisting (and possibly operating on) the change.

In some implementations, common components 550 forming the implementation of the layered data model can be leveraged across the platform architecture. On a server computer (which can include ephemeral serverless runtimes) operations on the layered data model can be deployed and/or compiled from their native language (e.g., the Go open source programming language) and optionally using GraphQL (or a similar API query language). For larger-scale compute demands (the optimization process that is run, e.g., when the user is done making changes and triggers an optimization of the schedule) the same implementation can be deployed but multi-threading can be used to generate results faster, e.g., running multi-threaded on many (50 to 100, or 64 to 100, 500, 1000 or more) central processing units (CPUs) 150 per solve, and a scalable worker pool can be used in some implementations. Note that the use of multi-threading with independent evolution (e.g., generation in an evolutionary AI algorithm) in the respective threads provides a substantial improvement in processing time (up to 100 times improvement) as compared to running a solve in a completely serialized fashion. Finally, the Application on the client computer can contain an embedded microservice, and potentially a multi-layer cache (as described above) with the same operations on the layered data model compiled as a WASM (WebAssembly) component.

In such implementations, the composable evaluation graph can be made available with the exact same code running in the compute engine, running in serverless scalable components from the API, or running compiled into WebAssembly and embedded as a microservice that has a communication protocol within the Web client itself. Thus, a consistent graph structure and consistent interfaces for data access are provided where the optimization can be readily done in real time despite the cloud-based service model, such that the editing of a constraint that affects a large amount data can be computed in near real-time (e.g., in real time) within the client application (e.g., within a browser program) and produce a result that is shown to the user.

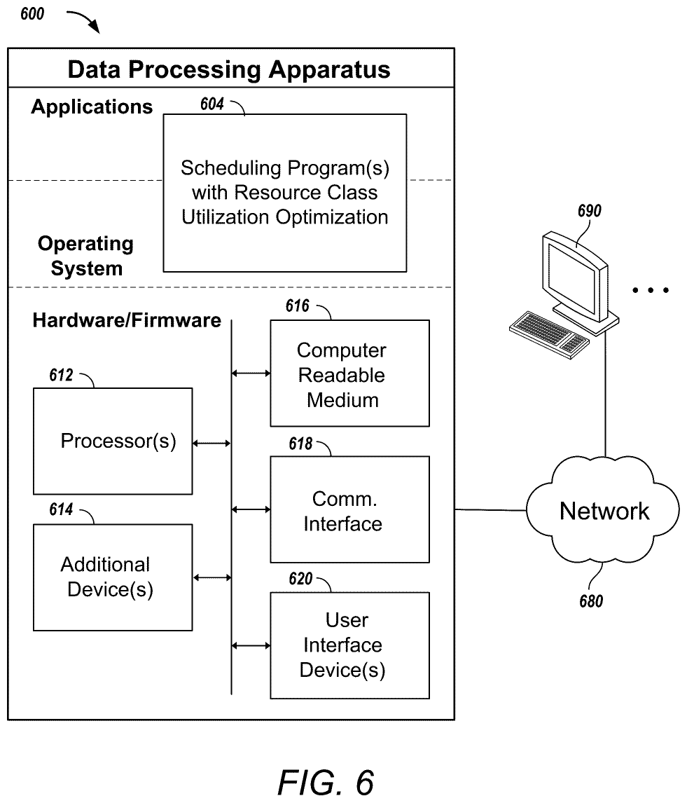

FIG. 6 is a schematic diagram of a data processing system including a data processing apparatus 600, which can be programmed as a client or as a server, and implements the processes described in this document. The data processing apparatus 600 is connected with one or more computers 690 through a network 680. While only one computer is shown in FIG. 6 as the data processing apparatus 600, multiple computers can be used. The data processing apparatus 600 includes various software modules, which can be distributed between an applications layer and an operating system. These can include executable and/or interpretable software programs or libraries, including tools and services of one or more scheduling programs 604 that implement resource class utilization optimization. The scheduling program(s) 604 can be a project scheduling program or a project tracking program, or the scheduling program(s) 604 can be an add-on to a project scheduling program or a project tracking program. In any case, the scheduling program(s) 604 can provide scenario planning functionality to assess the trade-offs associated with various possible schedules. The number of software modules used can vary from one implementation to another. Moreover, the software modules can be distributed on one or more data processing apparatus connected by one or more computer networks or other suitable communication networks.

The data processing apparatus 600 also includes hardware or firmware devices including one or more processors 612, one or more additional devices 614, a computer readable medium 616, a communication interface 618, and one or more user interface devices 620. Each processor 612 is capable of processing instructions for execution within the data processing apparatus 600. In some implementations, the processor 612 is a single or multi-threaded processor. Each processor 612 is capable of processing instructions stored on the computer readable medium 616 or on a storage device such as one of the additional devices 614. The data processing apparatus 600 uses the communication interface 618 to communicate with one or more computers 690, for example, over the network 680. Examples of user interface devices 620 include a display, a camera, a speaker, a microphone, a tactile feedback device, a keyboard, a mouse, and VR and/or AR equipment. The data processing apparatus 600 can store instructions that implement operations associated with the program(s) described above, for example, on the computer readable medium 616 or one or more additional devices 614, for example, one or more of a hard disk device, an optical disk device, a tape device, and a solid state memory device.

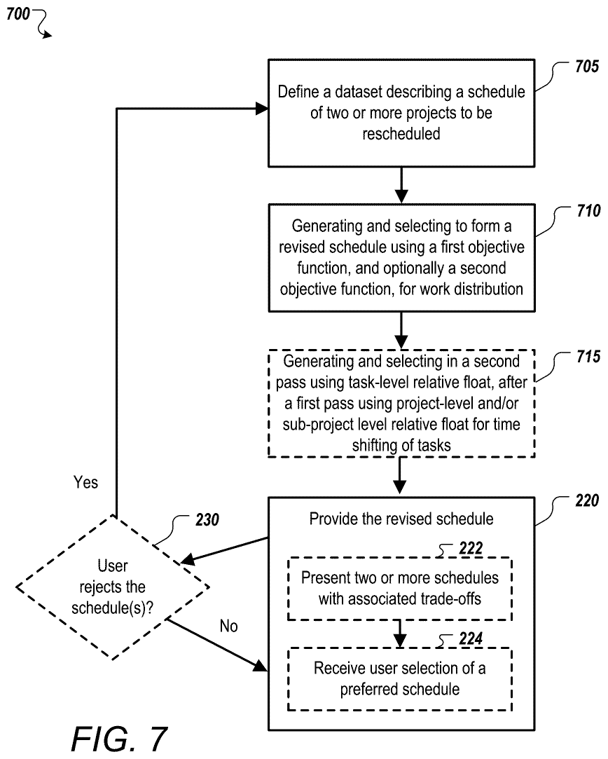

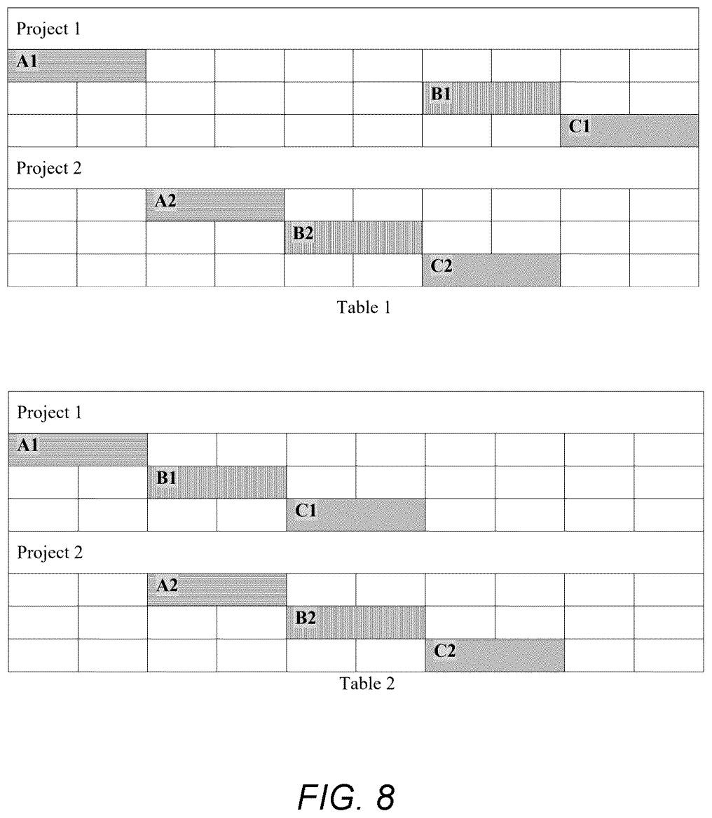

FIG. 7 shows another example of a process 700 of generative task scheduling. At 705, a dataset describing schedule(s) of one or more projects to be scheduled/rescheduled is defined by a scheduling computer program (e.g., generative task scheduler 116 and/or scheduling program(s) 604). The defining 705 can include obtaining 205, importing 305, presenting 310, and/or receiving 315, as described above. In addition, the presenting 310 can include presenting a current (or default) set of priority values assigned to tasks that share one or more specified resource classes, and the receiving 315 can include receiving user-specified changes to the priority values assigned to the tasks.

This allows the user to define a soft timing constraint for scheduling that encourages important projects and/or tasks be scheduled earlier in time. As noted above, an additional objective measure relevant to relative priority can be introduced as an additional dimension in the multi-objective formulation. In many situations it is desirable to be able to specify that a task requiring a class of resource is relatively more important than another also requiring the same class of resource. Specifically, that, if possible, the relatively less important task should be scheduled to start at or after the scheduled start time of the relatively more important task. However, relative priority should not be strictly enforced at the expense of optimizing resource utilization. Therefore, relative priority can be defined as an objective function rather than a constraint.

Thus, the user interface can be designed to allow the user to add priority values (e.g., integers from 0-100) to guide the multi-objective optimization algorithm (e.g., an evolutionary AI algorithm as described above) toward ordering tasks in a way the user likes. Thus, generating and selecting 710 to form a revised schedule can be done using one or more additional objective functions beyond an objective function for work distribution expressed as a deviation of a current utilization of a specified resource class from an ideal usage of the specified resource class (as described above in connection with generating 210, selecting 215, and maximizing utilization 320). In some implementations, the one or more additional objective functions include an objective function for work distribution expressed as a deviation of a current time-wise ordering of tasks that use the specified resource class from an ideal time-wise ordering of the tasks that use the specified resource class, where the ideal time-wise ordering of the tasks is determined from priority values assigned to the tasks that use the specified resource class. Thus, at 710, the generating and selecting 710 to form a revised schedule can be done by a scheduling computer program (e.g., generative task scheduler 116 and/or scheduling program(s) 604) using an additional objective function relating to relative priority of the various tasks to be scheduled.

In some implementations, this is done using a vector to represent each set of tasks that require a shared resource class, where the current time-wise ordering of tasks for that shared resource is defined by the current positions of the tasks referenced in the vector, and the ideal time-wise ordering of the tasks is determined by reordering the tasks in the vector based on the assigned priority values. Then, the runtime evaluation of the relative priority objective involves a simple comparison of vectors to assess deviation between the ideal time-wise ordering of the tasks and the current time-wise ordering of the tasks. Note that this deviation-based objective measure of the relative priority is very similar to the deviation-based objective measure of the current utilization of a specified resource class described above.

For example, assuming a defined set of n unique, but arbitrary integer priority values assigned to tasks requiring a given resource class we can normalize the set of relative priorities to the sequence of integers [1 . . . n]. Given the set of m tasks requiring the same resource class, we can then derive an objective vector of length m, each element being the normalized priority value for the task and the vector sorted in priority order. For example, for a set of 9 tasks, utilizing 3 unique priority values this results in a vector [1, 1, 1, 2, 2, 2, 3, 3, 3]. A similar objective vector can be derived for each resource class.

When evaluating a schedule, similar vectors are created for each resource class but are now sorted according to the tasks' scheduled start times. For example, resulting in one possible vector of [1, 1, 1, 2, 2, 3, 2, 3, 3]. An objective function can be derived that measures the divergence of priority from the objective priority ordering. For example using the L2 norm measuring the distance between the two vectors or another divergence metric such as Kullback-Leibler or Jensen-Shannon divergence. Using this method ensures that the greater the divergence of individual elements of the vectors, the objective measure scales exponentially. For example, the objective value of the example above would be 20.5 (1.4142), and the value of the divergence of [1, 1, 3, 2, 2, 2, 1, 3, 3] would be 80.5 (2.8284). Moreover, on a resource class by resource class basis, the weighting of the relative priority and utilization objectives can also be scaled to give equal or preferential weighting. For example, the evaluated objective function value for a given resource class can be considered as a single combined and normalized objective function where if the objective value of utilization is u, the objective value of priority is p, and the importance of priority is w, where w is [0 . . . 1], the composed objective function r=w*p+(1−w)*u, such that a value of w=0.5 gives equal importance to both priority and utilization and a value of w=0.8 would give considerable importance to priority over utilization.

In addition, in some implementations and when two or more projects are defined 705, a two-pass approach to scheduling/rescheduling is used. Two or more projects can share one or more resource classes and so need to be scheduled/rescheduled together, as part of an all-inclusive project. For such all-inclusive project scheduling, the user may want the tasks in each defined sub-project to be kept close together in time, even though this may not be appropriate when there are other sub-projects that are competing for the same resources. To achieve this goal, the generating and the selecting can be performed in two stages, a first stage of generating and selecting 710 applies relative float (described above) for schedule variation at a per project (or per sub-project) level, and a second stage of generating and selecting 715 applies relative float at an activity (or task) level. Note that, in some implementations, the generating and selecting 715 can also employ the second objective function for relative priority, as described above. Moreover, the two stage approach that is now described can be implemented in combination with using, or without using, the above-noted additional objective measure relevant to sequential continuity (seeking to minimize the amount of delay introduced between the start of a task and the finish of a dependent task) as an additional dimension in the multi-objective formulation.

As noted above, the two stage approach can include the first stage of generating and selecting 710 applying relative float for schedule variation at a per project or per sub-project level. Further, each sub-project can be predefined and/or user defined blocks of a work breakdown structure (WBS) in a single project or in two or more projects that need to be coordinated. Thus, using the two stage approach can be done within a single project at the sub-project level in the first stage.

When scheduling tasks to optimize resource utilization, individual tasks may be delayed from their earliest start time. The choice of the amount of delay to apply to each of a given set of tasks requiring the same class of resource can result in an undesirable lack of continuity in common subsets of the work breakdown structure (WBS). For example, consider two independent subtrees of the WBS each consisting of three dependent tasks, A1, B1, C1, and A2, B2, C2. And, where tasks A1 and A2 require resource class A, and similarly for B and C. The schedule shown in Table 1 below exhibits an optimized use of each resource class.

However, the first work breakdown shown above (A1, A2, A3) has an undesirable break in continuity compared to an alternative schedule shown below in Table 2. While this is a simple example, in a schedule with thousands of subtrees of the WBS, ensuring reasonable continuity while also optimizing resource usage has an astronomical number of possible arrangements.

Using the concept of a multi-resolution method (conceptually similar to multi-grid methods in numerical algorithms) the population of schedules in the evolutionary algorithm can be preconditioned in the first stage of a two stage approach. First, the initial population is constrained such that the subtrees of the WBS are delayed as a block, i.e., in a subtree where A₁->B₁->C₁ (in a precedence relationship), only A₁ can be delayed and B₁ and C₁ are scheduled as soon as possible subject to their precedence relationships and other constraints. This can be referred to as block constraining (where relative float is applied to the entire block versus per activity or task). The evolutionary algorithm run in this phase has as its result a coarse (low resolution) result, but continuity is strictly maintained. Next, the block constraints are removed and the second phase of the evolutionary algorithm proceeds. However, the population is now preconditioned so that a high-resolution result is obtained but tends to preserve the desirable continuity. In addition, in this second phase an objective measure of continuity (the amount of optional delay used) can be introduced to add additional pressure to preserve continuity.

In general, in the first stage, projects (or sub-projects) are moved around to generate the different scheduling options to select from, and in the second stage, activities (or tasks) are moved around to generate the different scheduling options to select from. Thus, the tasks within each project (or sub-project) are kept together in the first stage when an initial, rough schedule is produced, and then the second stage need not do that much moving of tasks around in the schedule to achieve an optimal solution. The final resulting schedule provides more sequential continuity within each project (or sub-project) as may desired by the user, without requiring the use of a sequential continuity objective function as an additional dimension in the multi-objective formulation.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as hard drive in a computer system or an optical disc sold through retail channels, or an embedded system. The computer-readable medium can be acquired separately and later encoded with the one or more modules of computer program instructions, e.g., after delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any suitable form of programming language, including compiled or interpreted languages, declarative or procedural languages, and it can be deployed in any suitable form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., an LCD (liquid crystal display) display device, an OLED (organic light emitting diode) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any suitable form of sensory feedback, e.g., visual feedback, auditory feedback, or tactile feedback; and input from the user can be received in any suitable form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a browser user interface through which a user can interact with an implementation of the subject matter described is this specification, or any combination of one or more such back-end, middleware, or front-end components. The components of the system can be interconnected by any suitable form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. In addition, actions recited in the claims can be performed in a different order and still achieve desirable results.

Examples: Although the present application is defined in the attached claims, it should be understood that the present invention can also (additionally or alternatively) be defined in accordance with the following examples:

Example 1. A method comprising: obtaining, by a scheduling computer program, a dataset describing a schedule of one or more projects to be rescheduled, the dataset comprising a work breakdown structure of tasks to be scheduled, resource requirements, and dependencies between or among the tasks; generating, by the scheduling computer program, variations of the schedule, wherein each of the variations of the schedule have different characteristics that determine for the tasks in the schedule when each task is scheduled in time, and each of the variations satisfy the resource requirements, and the dependencies; selecting, by the scheduling computer program, among the different characteristics for the tasks in the variations of the schedule to form a revised schedule of the one or more projects; and providing, by the scheduling computer program, the revised schedule of the one or more projects for display to a user or for output to manage the one or more projects.

Example 2. The method of Example 1, wherein the dataset comprises one or more scheduling constraints in addition to the dependencies, and each of the variations satisfy the one or more scheduling constraints in addition to the dependencies.

Example 3. The method of any one of Examples 1-2, wherein the generating and the selecting are performed by an evolutionary artificial intelligence algorithm.

Example 4. The method of any one of Examples 1-3, wherein the one or more projects are two or more projects that share at least one resource class, the one or more scheduling constraints comprise at least one time constraint for each of the two or more projects, and the generating and the selecting form the revised schedule by maximizing utilization of the at least one resource class while also meeting the at least one time constraint for each of the two or more projects.

Example 5. The method of any one of Examples 1-4, comprising employing a layered data model for the dataset, wherein the layered data model comprises a first layer specifying a topology of a graph representing the schedule; a second layer specifying at least edit operations that make local changes to the first layer; and a third layer specifying the graph representing the schedule, including all details of the dependencies between or among the tasks in the schedule and all scheduled start and end times for the tasks in the schedule.

Example 6. The method of Example 5, wherein the scheduling computer program runs at least on a server computer remote from a client computer operated by the user, the first layer of the layered data model is fully loaded into memory of the client computer, and updates to the second layer in response to edit operations are concurrently performed locally at the client computer and persisted to the server computer.

Example 7. The method of any one of Examples 1-6, comprising: presenting, in a graphical user interface, a currently planned usage of a selected resource class and a calculated ideal usage of the selected resource class; and receiving, via the graphical user interface, user input that changes a shape of the calculated ideal usage of the selected resource class to create a user-specified ideal usage of the selected resource class; wherein the generating and the selecting form the revised schedule by modifying the currently planned usage of the selected resource class to approximate the user-specified ideal usage based on an objective function for work distribution expressed as a deviation of the selected resource class's utilization from the user-specified ideal usage of the selected resource class.

Example 8. The method of Example 7, wherein the graphical user interface shows time on a first axis and workload on a second axis, and the user input changes a start date for usage of the selected resource class, an end date for usage of the selected resource class, a ramp-up curve for the workload for the selected resource class, a ramp-down curve for the workload for the selected resource class, or a combination thereof.

Example 9. The method of any one of Examples 7-8, wherein the objective function for work distribution uses a non-uniform and discontinuous independent variable that represents clock time as a monotonically increasing, cumulative amount of available working time since a start time.

Example 10. The method of Example 9, comprising providing both a concurrency-safe lazy-construction mode and a high-performance lock-free read-only mode for assessing the clock time.

Example 11. The method of any one of Examples 1-10, wherein the generating and the selecting form the revised schedule by modifying the currently planned usage of the selected resource class based on (i) a first objective function for work distribution expressed as a deviation of a current utilization of a specified resource class from an ideal usage of the specified resource class and (ii) a second objective function for work distribution expressed as a deviation of a current time-wise ordering of tasks that use the specified resource class from an ideal time-wise ordering of the tasks that use the specified resource class, wherein the ideal time-wise ordering of the tasks is determined from priority values assigned to the tasks that use the specified resource class.

Example 12. The method of any one of Examples 1-11, wherein the generating and the selecting are performed in two stages, relative float for schedule variation is applied per project or per sub-project in an initial one of the two stages, and relative float for schedule variation is applied per activity in a subsequent one of the two stages.

Example 13. A non-transitory computer-readable medium encoding a computer aided design program operable to cause one or more data processing apparatus to perform operations as recited in any of Examples 1-12.

Example 14. A system comprising: one or more data processing apparatus; and one or more non-transitory computer-readable mediums encoding instructions that are performable by the one or more data processing apparatus to perform operations as recited in any of Examples 1-12.

What is claimed is:

1. A method comprising:
obtaining, by a scheduling computer program, a dataset describing a schedule of one or more projects to be rescheduled, the dataset comprising a work breakdown structure of tasks to be scheduled, resource requirements, and dependencies between or among the tasks;
generating, by the scheduling computer program, variations of the schedule, wherein each of the variations of the schedule have different characteristics that determine for the tasks in the schedule when each task is scheduled in time, and each of the variations satisfy the resource requirements, and the dependencies;
selecting, by the scheduling computer program, among the different characteristics for the tasks in the variations of the schedule to form a revised schedule of the one or more projects; and
providing, by the scheduling computer program, the revised schedule of the one or more projects for display to a user or for output to manage the one or more projects.

2. The method of claim 1, wherein the dataset comprises one or more scheduling constraints in addition to the dependencies, and each of the variations satisfy the one or more scheduling constraints in addition to the dependencies.

3. The method of claim 1, wherein the generating and the selecting are performed by an evolutionary artificial intelligence algorithm.

4. The method of claim 1, wherein the one or more projects are two or more projects that share at least one resource class, the one or more scheduling constraints comprise at least one time constraint for each of the two or more projects, and the generating and the selecting form the revised schedule by maximizing utilization of the at least one resource class while also meeting the at least one time constraint for each of the two or more projects.

5. The method of claim 1, comprising employing a layered data model for the dataset, wherein the layered data model comprises:
a first layer specifying a topology of a graph representing the schedule;
a second layer specifying at least edit operations that make local changes to the first layer; and
a third layer specifying the graph representing the schedule, including all details of the dependencies between or among the tasks in the schedule and all scheduled start and end times for the tasks in the schedule.

6. The method of claim 5, wherein the scheduling computer program runs at least on a server computer remote from a client computer operated by the user, the first layer of the layered data model is fully loaded into memory of the client computer, and updates to the second layer in response to edit operations are concurrently performed locally at the client computer and persisted to the server computer.

7. The method of claim 1, comprising:
presenting, in a graphical user interface, a currently planned usage of a selected resource class and a calculated ideal usage of the selected resource class; and
receiving, via the graphical user interface, user input that changes a shape of the calculated ideal usage of the selected resource class to create a user-specified ideal usage of the selected resource class;
wherein the generating and the selecting form the revised schedule by modifying the currently planned usage of the selected resource class to approximate the user-specified ideal usage based on an objective function for work distribution expressed as a deviation of the selected resource class's utilization from the user-specified ideal usage of the selected resource class.

8. The method of claim 7, wherein the graphical user interface shows time on a first axis and workload on a second axis, and the user input changes a start date for usage of the selected resource class, an end date for usage of the selected resource class, a ramp-up curve for the workload for the selected resource class, a ramp-down curve for the workload for the selected resource class, or a combination thereof.

9. The method of claim 7, wherein the objective function for work distribution uses a non-uniform and discontinuous independent variable that represents clock time as a monotonically increasing, cumulative amount of available working time since a start time.

10. The method of claim 9, comprising providing both a concurrency-safe lazy-construction mode and a high-performance lock-free read-only mode for assessing the clock time.

11. The method of claim 7, wherein the generating and the selecting form the revised schedule by modifying the currently planned usage of the selected resource class based on (i) a first objective function for work distribution expressed as a deviation of a current utilization of a specified resource class from an ideal usage of the specified resource class and (ii) a second objective function for work distribution expressed as a deviation of a current time-wise ordering of tasks that use the specified resource class from an ideal time-wise ordering of the tasks that use the specified resource class, wherein the ideal time-wise ordering of the tasks is determined from priority values assigned to the tasks that use the specified resource class.

12. The method of claim 1, wherein the generating and the selecting are performed in two stages, relative float for schedule variation is applied per project or per sub-project in an initial one of the two stages, and relative float for schedule variation is applied per activity in a subsequent one of the two stages.

13. A non-transitory computer-readable medium encoding a scheduling computer program operable to cause one or more data processing apparatus to perform operations comprising:
obtaining a dataset describing a schedule of one or more projects to be rescheduled, the dataset comprising a work breakdown structure of tasks to be scheduled, resource requirements, and dependencies between or among the tasks;
generating variations of the schedule, wherein each of the variations of the schedule have different characteristics that determine for the tasks in the schedule when each task is scheduled in time, and each of the variations satisfy the resource requirements, and the dependencies;
selecting among the different characteristics for the tasks in the variations of the schedule to form a revised schedule of the one or more projects; and
providing the revised schedule of the one or more projects for display to a user or for output to manage the one or more projects.

14. The non-transitory computer-readable medium of claim 13, wherein the one or more projects are two or more projects that share at least one resource class, the one or more scheduling constraints comprise at least one time constraint for each of the two or more projects, and the generating and the selecting form the revised schedule by maximizing utilization of the at least one resource class while also meeting the at least one time constraint for each of the two or more projects.

15. The non-transitory computer-readable medium of claim 13, wherein the operations comprise employing a layered data model for the dataset, and the layered data model comprises:
a first layer specifying a topology of a graph representing the schedule;
a second layer specifying at least edit operations that make local changes to the first layer; and
a third layer specifying the graph representing the schedule, including all details of the dependencies between or among the tasks in the schedule and all scheduled start and end times for the tasks in the schedule.

16. The non-transitory computer-readable medium of claim 15, wherein the scheduling computer program runs at least on a server computer remote from a client computer operated by the user, the first layer of the layered data model is fully loaded into memory of the client computer, and updates to the second layer in response to edit operations are concurrently performed locally at the client computer and persisted to the server computer.

17. The non-transitory computer-readable medium of claim 13, wherein the operations comprise:
presenting, in a graphical user interface, a currently planned usage of a selected resource class and a calculated ideal usage of the selected resource class; and
receiving, via the graphical user interface, user input that changes a shape of the calculated ideal usage of the selected resource class to create a user-specified ideal usage of the selected resource class;
wherein the generating and the selecting form the revised schedule by modifying the currently planned usage of the selected resource class to approximate the user-specified ideal usage based on an objective function for work distribution expressed as a deviation of the selected resource class's utilization from the user-specified ideal usage of the selected resource class.

18. The non-transitory computer-readable medium of claim 17, wherein the objective function for work distribution uses a non-uniform and discontinuous independent variable that represents clock time as a monotonically increasing, cumulative amount of available working time since a start time.

19. The non-transitory computer-readable medium of claim 18, wherein the operations comprise providing both a concurrency-safe lazy-construction mode and a high-performance lock-free read-only mode for assessing the clock time.

20. The non-transitory computer-readable medium of claim 17, wherein the generating and the selecting form the revised schedule by modifying the currently planned usage of the selected resource class based on (i) a first objective function for work distribution expressed as a deviation of a current utilization of a specified resource class from an ideal usage of the specified resource class and (ii) a second objective function for work distribution expressed as a deviation of a current time-wise ordering of tasks that use the specified resource class from an ideal time-wise ordering of the tasks that use the specified resource class, wherein the ideal time-wise ordering of the tasks is determined from priority values assigned to the tasks that use the specified resource class.

21. The non-transitory computer-readable medium of claim 13, wherein the generating and the selecting are performed in two stages, relative float for schedule variation is applied per project or per sub-project in an initial one of the two stages, and relative float for schedule variation is applied per activity in a subsequent one of the two stages.

22. A system comprising:
one or more data processing apparatus; and
one or more non-transitory computer-readable mediums encoding instructions that are performable by the one or more data processing apparatus to perform operations comprising:
obtaining a dataset describing a schedule of one or more projects to be rescheduled, the dataset comprising a work breakdown structure of tasks to be scheduled, resource requirements, and dependencies between or among the tasks;
generating variations of the schedule, wherein each of the variations of the schedule have different characteristics that determine for the tasks in the schedule when each task is scheduled in time, and each of the variations satisfy the resource requirements, and the dependencies;
selecting among the different characteristics for the tasks in the variations of the schedule to form a revised schedule of the one or more projects; and
providing the revised schedule of the one or more projects for display to a user or for output to manage the one or more projects.

23. The system of claim 22, wherein the one or more projects are two or more projects that share at least one resource class, the one or more scheduling constraints comprise at least one time constraint for each of the two or more projects, and the generating and the selecting form the revised schedule by maximizing utilization of the at least one resource class while also meeting the at least one time constraint for each of the two or more projects.

24. The system of claim 22, wherein the operations comprise employing a layered data model for the dataset, and the layered data model comprises:
a first layer specifying a topology of a graph representing the schedule;
a second layer specifying at least edit operations that make local changes to the first layer; and
a third layer specifying the graph representing the schedule, including all details of the dependencies between or among the tasks in the schedule and all scheduled start and end times for the tasks in the schedule.

25. The system of claim 24, wherein the one or more data processing apparatus comprise a client computer operated by the user and a server computer remote from the client computer, the first layer of the layered data model is fully loaded into memory of the client computer, and updates to the second layer in response to edit operations are concurrently performed locally at the client computer and persisted to the server computer.

26. The system of claim 22, wherein the operations comprise:
presenting, in a graphical user interface, a currently planned usage of a selected resource class and a calculated ideal usage of the selected resource class; and
receiving, via the graphical user interface, user input that changes a shape of the calculated ideal usage of the selected resource class to create a user-specified ideal usage of the selected resource class;
wherein the generating and the selecting form the revised schedule by modifying the currently planned usage of the selected resource class to approximate the user-specified ideal usage based on an objective function for work distribution expressed as a deviation of the selected resource class's utilization from the user-specified ideal usage of the selected resource class.

27. The system of claim 26, wherein the objective function for work distribution uses a non-uniform and discontinuous independent variable that represents clock time as a monotonically increasing, cumulative amount of available working time since a start time.

28. The system of claim 27, wherein the operations comprise providing both a concurrency-safe lazy-construction mode and a high-performance lock-free read-only mode for assessing the clock time.

29. The system of claim 26, wherein the generating and the selecting form the revised schedule by modifying the currently planned usage of the selected resource class based on (i) a first objective function for work distribution expressed as a deviation of a current utilization of a specified resource class from an ideal usage of the specified resource class and (ii) a second objective function for work distribution expressed as a deviation of a current time-wise ordering of tasks that use the specified resource class from an ideal time-wise ordering of the tasks that use the specified resource class, wherein the ideal time-wise ordering of the tasks is determined from priority values assigned to the tasks that use the specified resource class.

30. The system of claim 22, wherein the generating and the selecting are performed in two stages, relative float for schedule variation is applied per project or per sub-project in an initial one of the two stages, and relative float for schedule variation is applied per activity in a subsequent one of the two stages.
